(19) United States
(12) Patent Application Publication
(10) Pub. No.: US 2024/0222494 A1
(43) Pub. Date: Jul. 4, 2024

(54) SEMICONDUCTOR DEVICE AND METHODS FOR FORMING THE SAME

(71) Applicant: Vanguard International Semiconductor Corporation, Hsinchu (TW)

(72) Inventors: Chen-Dong TZOU, Taipei City (TW); Chih-Cherng LIAO, Zhudong Township (TW); Chien-Hsien SONG, Kaohsiung City (TW); Chia-Hao LEE, Zhubei City (TW); Tzu-Hsuan CHEN, Hsinchu City (TW)

(73) Assignee: Vanguard International Semiconductor Corporation, Hsinchu (TW)

(21) Appl. No.: 18/150,106

(22) Filed: Jan. 4, 2023

(51) Int. Cl. H01L 29/78; H01L 29/06; H01L 29/40; H01L 29/417; H01L 29/66

(52) U.S. Cl. CPC H01L 29/7813; H01L 29/0696; H01L 29/401; H01L 29/41741; H01L 29/41775; H01L 29/66734; H01L 29/7811

(57) ABSTRACT

A semiconductor device includes a substrate having a first conductivity type, an epitaxial layer on the substrate and having the first conductivity type, a trench structure extending from the top surface of the epitaxial layer into the epitaxial layer, and a well region extending into the epitaxial layer and has the second conductivity type. The first sidewall of the well region is in contact with the trench structure. The trench structure includes a conductive portion and an insulating layer that covers the sidewalls and the bottom portion of the conductive portion. A drift region that has the first conductivity type is adjacent to and under the well region. The drift region is in contact with the second sidewall and the bottom surface of the well region. The semiconductor device further includes a gate structure on the top surface of the epitaxial layer and over the well region.

### BACKGROUND

### Technical Field

The disclosure relates to a semiconductor device and methods for forming the same, and it relates to a semiconductor device with improved electrical characteristics and methods for forming the same.

### Description of the Related Art

The integration density of different electronic components is being continuously improved in the semiconductor industry. Continuously decreasing the minimum size of components allows more and more components to be integrated into a given area. For example, trench gate metal-oxide-semiconductor field effect transistors, which are widely used in power switch components, are designed to have a vertical structure to reduce the cell pitch and increase their functional density. In a trench gate metal-oxide-semiconductor field effect transistor (MOSFET), the back of the chip serves as a drain, while the sources and gates of various transistors are formed on the front of the chip. Accordingly, the flow of the driving current of a planar semiconductor device is in a horizontal direction, while the flow of the driving current of a trench gate semiconductor device is in a vertical direction, so that the trench gate semiconductor device can achieve a high-withstand voltage and a low on-resistance. In addition, existing semiconductor devices that include both a planar gate structure and a trench gate structure have been developed. However, although existing semiconductor devices and methods for forming the same are generally adequate for their intended purposes, they have not been entirely satisfactory in all respects.

### SUMMARY

Some embodiments of the present disclosure provide semiconductor devices. A semiconductor device includes a substrate, an epitaxial layer, a trench structure, a well region and a gate structure. The substrate has a first conductivity type. The epitaxial layer is formed on the substrate and the epitaxial layer has the first conductivity type. The trench structure extends downward from the top surface of the epitaxial layer into the epitaxial layer. The trench structure includes a conductive portion and an insulating layer that covers sidewalls and the bottom portion of the conductive portion. The well region extends downward from the top surface of the epitaxial layer into the epitaxial layer. In addition, the well region has a second conductivity type, and the first sidewall of the well region is in contact with the trench structure. In addition, a drift region that has the first conductivity type is adjacent to and under the well region. The drift region is in contact with the second sidewall and the bottom surface of the well region. The gate structure is formed on the top surface of the epitaxial layer and over the well region.

Some embodiments of the present disclosure provide semiconductor structures. A semiconductor structure includes several aforementioned semiconductor devices, and one or more of the trench structures of the semiconductor devices are electrically connected to one or more source terminals of the semiconductor devices. In addition, one or more remaining trench structures of the semiconductor devices are electrically connected to one or more gate structures of the semiconductor devices.

Some embodiments of the present disclosure provide methods for forming a semiconductor device. A method for forming a semiconductor device includes providing a substrate that has a first conductivity type, and forming an epitaxial layer on the substrate. The epitaxial layer has the first conductivity type. The method for forming the semiconductor device further includes forming a trench structure that extends downward from the top surface of the epitaxial layer into the epitaxial layer. The trench structure includes a conductive portion and an insulating layer that covers the sidewalls and the bottom portion of the conductive portion. The method for forming the semiconductor device further includes forming a well region that extends downward from the top surface of the epitaxial layer into the epitaxial layer. The first sidewall of the well region is in contact with the trench structure, and the well region has the second conductivity type. A drift region has the first conductivity type and is adjacent to one side of the well region and under the well region. The drift region is in contact with the second sidewall and the bottom surface of the well region. The method for forming the semiconductor device further includes forming a gate structure on the top surface of the epitaxial layer and over the well region.

A detailed description is given in the following embodiments with reference to the accompanying drawings.

### BRIEF DESCRIPTION OF THE DRAWINGS

The embodiments of the disclosure can be more fully understood by reading the subsequent detailed description and examples with references made to the accompanying drawings. For clarity of illustration, various elements in the drawings may not be drawn to scale, wherein:

FIG. 1A, FIG. 1B, FIG. 1C, FIG. 1D, FIG. 1E and FIG. 1F illustrate cross-sectional views of intermediate stages of a method for forming a semiconductor device, in accordance with some embodiments of the present disclosure.

FIG. 2 is a cross-sectional view of an intermediate stage of a semiconductor device 20, in accordance with some embodiments of the present disclosure.

FIG. 3 is a cross-sectional view of a conventional semiconductor device.

FIG. 4 is a simulation result that shows the characteristic on-resistance (Ron-sp; mΩ× mm²) of each of the semiconductor devices at different breakdown voltages.

FIG. 5A is a simulation result that shows the gate voltage (Vg) changes with time when a conventional TG structure and a TS structure of an embodiment are in the off state.

FIG. 5B is a simulation result that shows the gate voltage (Vg) changes with time when a conventional TG structure and a TS structure of an embodiment are in the on state.

FIG. 6A is a simulation result that shows the drain voltage (Vd) or drain current (Id) changes with time when a conventional TG structure and a TS structure of an embodiment are in the off state.

FIG. 6B is a simulation result that shows the drain voltage (Vd) or drain current (Id) changes with time when a conventional TG structure and a TS structure of an embodiment are in the on state.

FIG. 7A is a simulation result that shows the power changes with time when a conventional TG structure and a TS structure of an embodiment are in the off state.

FIG. 7B is a simulation result that shows the power changes with time when a conventional TG structure and a TS structure of an embodiment are in the on state.

### DETAILED DESCRIPTION

The following description provides various embodiments, or examples, for implementing different features of the present disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numbers and/or letters in the various examples. This repetition is for the purpose of simplicity and clarity and does not in itself dictate a relationship between the various embodiments and/or configurations discussed.

In addition, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments are described below. Throughout the various views and illustrative embodiments, similar reference numbers are used to designate similar features/components. It should be understood that additional operations can be provided before, during, and after the method, and some of the operations can be replaced or eliminated for other embodiments of the method.

The present disclosure provides a semiconductor device and a method for forming the same. In some embodiments, a semiconductor device with a good figure of merit (FOM) can be obtained, and the electrical characteristics of the semiconductor device can be greatly improved. For example, the semiconductor device of the embodiments has a faster response time when it is turned off and turned on. In addition, the switching energy loss (that is caused by the switching between the on-state and the off-state of the device) of the semiconductor device, in accordance with some embodiments of the present disclosure, can be greatly reduced. The method for forming a semiconductor device, in accordance with some embodiments of the present disclosure, has a relatively simple manufacturing process and does not require expensive manufacturing steps. In addition, the semiconductor device of the embodiments can be flexibly configured to have suitable circuit connection, so that the semiconductor device is applicable to the circuit systems that are required for low-frequency operation or high-frequency operation, depending on the practical requirements of the application. The embodiments can be applied to metal-oxide-semiconductor (MOS) devices, such as metal-oxide-semiconductor field effect transistors (MOSFETs). In some of the embodiments described below, a MOSFET that includes one or more planar gate structures and one or more conductive trench structures is used to illustrate a semiconductor device. However, the present disclosure is not limited thereto. Some embodiments of the present disclosure can be applied to other types of semiconductor devices.

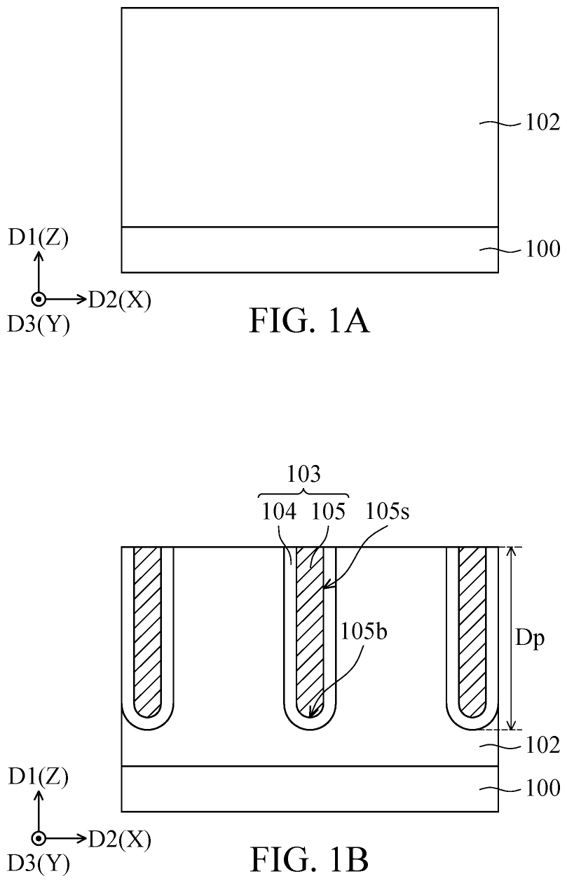

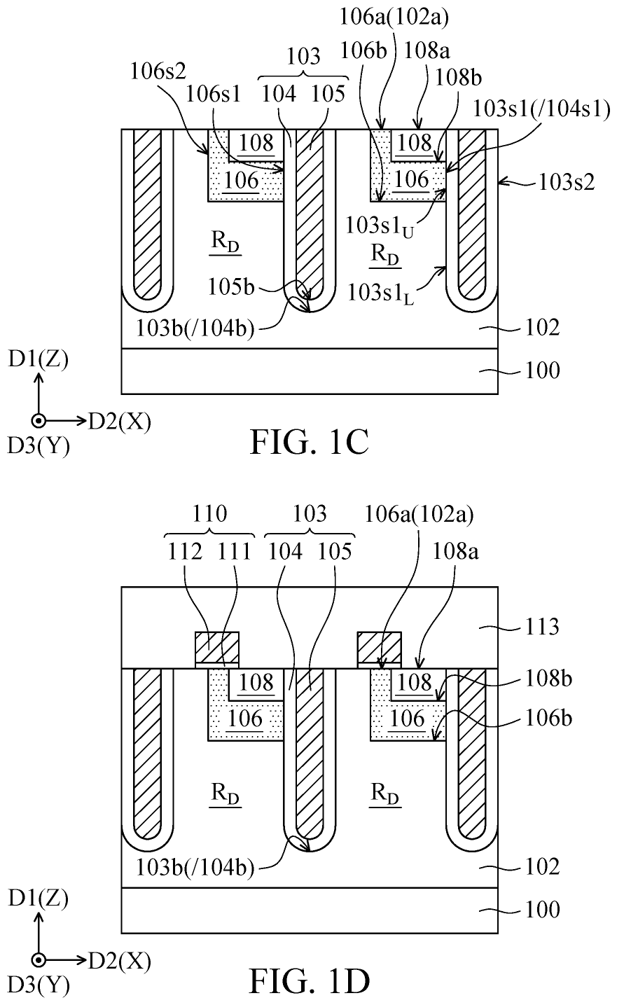

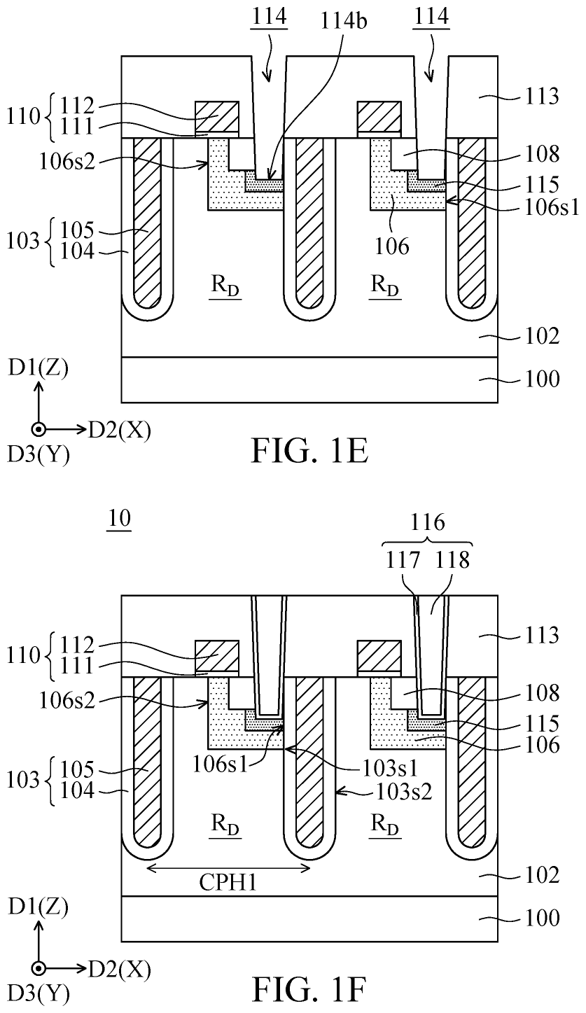

FIG. 1A-FIG. 1F illustrate cross-sectional views of intermediate stages of a method for forming a semiconductor device, in accordance with some embodiments of the present disclosure.

Referring to FIG. 1A, a substrate 100 that has a first conductivity type is provided according to some embodiments. In some embodiments, the substrate 100 is a bulk semiconductor substrate, such as a semiconductor wafer. For example, the substrate 100 is a silicon wafer. In some embodiments, the substrate 100 includes silicon or another elemental semiconductor material. In some other embodiments, the substrate 100 includes another elemental semiconductor material such as germanium (Ge). In some embodiments, the substrate 100 includes compound semiconductor, such as silicon carbide, gallium nitride, or another suitable material. In some embodiments, the substrate 100 includes alloy semiconductor, such as silicon germanium, silicon germanium carbide, or another suitable alloy semiconductor. In some embodiments, the substrate 100 includes several material layers that form a multilayer structure. The materials of the substrate 100 include silicon/silicon germanium, silicon/silicon carbide, or another suitable combination of the material layers.

In this exemplified embodiment, the substrate 100 is, for example, a silicon wafer that is doped with dopants of the first conductivity type. In the application of a vertical trench-gate MOSFET, the substrate 100 that has the first conductivity type can act as a drain region of the semiconductor device. In addition, in this exemplified embodiment, the first conductivity type is n-type, but the present disclosure is not limited thereto. In some other embodiments, the first conductivity type can be p-type.

In some embodiments, an epitaxial growth process is performed to form an epitaxial layer 102 on the substrate 100. The substrate 100 and the epitaxial layer 102 have the same conductivity type, such as the first conductivity type. In this exemplified embodiment, the epitaxial layer 102 is n-type. In some embodiments, the doping concentration of the epitaxial layer 102 is less than the doping concentration of the substrate 100. In the application of a semiconductor device, such as a vertical trench gate MOSFET, the epitaxial layer 102 that has the first conductivity type (such as n-type) can function as a drift region of the semiconductor device.

In some embodiments, the aforementioned epitaxial growth process can be performed by using a metal organic chemical vapor deposition (MOCVD) process, a plasma-enhanced chemical vapor deposition (PECVD) process, a molecular beam epitaxy (MBE) process, a hydride vapor phase epitaxy (HVPE), a liquid phase epitaxy (LPE) process, a chloride vapor phase epitaxy (Cl-VPE) process, another suitable process or a combination thereof to form the epitaxial layer 102.

Next, referring to FIG. 1B, several trench structures 103 are formed in the epitaxial layer 102, in accordance with some embodiments of the present disclosure. Each trench structure 103 includes an insulating layer 104 and a conductive portion 105. The insulating layer 104 covers the sidewalls 105s and the bottom 105b of the conductive portion 105. In some embodiments, as shown in FIG. 1B, each of the trench structures 103 that is formed in the epitaxial layer 102 extends in the first direction D1 (such as Z direction), and the trench structures 103 are separated from each other by a distance in the second direction D2 (such as X direction).

According to suitable arrangement of the trench structure 103 and other components that are formed subsequently, the electrical performance of the semiconductor device can be improved. For example, if the trench structure 103 is electrically connected to the gate electrode in the subsequent process, in accordance with some embodiments of the present disclosure, the on-resistance of the semiconductor device can be greatly reduced. If the trench structure 103 is electrically connected to the source terminal in the subsequent process, in accordance with some embodiments of the present disclosure, the semiconductor device has good dynamic characteristic while the on-resistance is still reduced effectively. In addition, compared to the conventional structure, the switching time between turn on and turn off the semiconductor device of the embodiments can be reduced. In addition, compared to the conventional structure, the switching energy loss of the semiconductor device of the embodiments can be greatly reduced.

According to some embodiments, positions of the above-mentioned trench structures 103 may be defined by using a lithographic patterning process. In some exemplified embodiments, a mask (not shown) is formed over the epitaxial layer 102, and the mask has several openings to expose the top surface 102a of the epitaxial layer 102. In some embodiments, the mask is a patterned photoresist that includes one or more photoresist materials. In some other embodiments, the mask is a hard mask (HM) that includes an oxide layer and a nitride layer. In some embodiments that the patterned photoresist is used as a mask, the aforementioned lithographic patterning process includes photoresist coating (e.g., spin-on coating), soft baking, mask alignment, exposure, post-exposure baking, developing the photoresist, rinsing and drying (e.g., hard baking), another suitable process or a combination of the foregoing processes to form those openings.

Next, several portions of the epitaxial layer 102 can be removed through the openings of the mask by, for example, one or more etching processes to form trenches (not shown) in the epitaxial layer 102. In some embodiments, the positions of the trenches correspond to the positions of the trench structures 103 shown in FIG. 1B. The depth of these trenches in the epitaxial layer 102 (for example, in the first direction D1) is equal to the depth Dp of the subsequently formed trench structures 103 in the epitaxial layer 102 (for example, in the first direction D1).

In addition, in some embodiments, the aforementioned etching process includes a dry etching process, a wet etching process, a plasma etching process, a reactive ion etching process, another suitable process, or a combination of the foregoing processes. In addition, it should be noted that dimensions, shapes and positions of the trenches and the trench structures 103 that are formed in the trenches are provided for illustrative purposes, and the embodiments of the present invention are not limited thereto.

According to some embodiments, after the trenches are formed in the epitaxial layer 102, the mask can be removed by an ashing process, a wet etching process (such as acid etching), or another acceptable and suitable removing process. After the mask is removed, a cleaning process can be selectively and optionally performed to remove residual material.

In some embodiments, after forming the trenches, an insulating material (not shown) can be conformably deposited on the top surface 102a of the epitaxial layer 102. The insulating material is deposited in the trenches and acts as a liner layer on the sidewalls and the bottom surface of each of the trenches.

The trench structures 103 of the embodiments can be electrically connected to source electrodes or gate electrodes. The above-mentioned insulating material that is deposited in the trenches can be selected properly according to the electrical connection of the trench structures 103 in the applications.

In some embodiments that the trench structures 103 are electrically connected to the source electrodes, the insulating material can be silicon oxide, germanium oxide, another suitable semiconductor oxide material, or a combination of the aforementioned materials. In some exemplified embodiments, the insulating material can be isotropically formed on the sidewalls and the bottom surfaces of the trenches and the top surface 102a of the epitaxial layer 102 by using an oxidation process. In some embodiments, the oxidation process may include a thermal oxidation process, a radical oxidation process, or another suitable process. In some embodiments, a thermal process can be selectively performed on the insulating material to increase the material density of the insulating material. In some embodiments, the aforementioned thermal process can be a rapid thermal annealing (RTA) process.

In some embodiments that the trench structures 103 are electrically connected to the gate electrodes, that is, the trench structures 103 act as trench gate structures, the insulating material can be silicon oxide, hafnium oxide, zirconium oxide, aluminum oxide, hafnium-aluminum-oxide alloy, hafnium silicon dioxide, hafnium silicon oxynitride, hafnium tantalum oxide, hafnium titanium oxide, hafnium zirconium oxide, another suitable high dielectric constant (high-k) dielectric material, or a combination of the aforementioned materials. In some embodiments, an insulating material can be formed on the sidewalls and the bottom surfaces of the trenches and on the top surface 102a of the epitaxial layer 102 by a deposition process, such as an isotropic deposition process. In addition, the aforementioned deposition process can be a physical vapor deposition (PVD) process, a chemical vapor deposition (CVD) process, an atomic layer deposition (ALD) process, another suitable deposition processes, or a combination of the aforementioned processes.

Next, a conductive material (not shown) is deposited on the insulating material by using a deposition process, and the conductive material fills the spaces remained in the trenches, in accordance with some embodiments. A thermal process, such as an annealing process, can be selectively performed on the conductive material. In some embodiments, the conductive material is a single-layer structure or a multilayer structure. The conductive material may include amorphous silicon, polysilicon, or a combination of the aforementioned materials. In some exemplified embodiments, the aforementioned deposition process can be a physical vapor deposition (PVD) process, a chemical vapor deposition (CVD) process, another suitable deposition processes, or a combination of the aforementioned processes.

Next, excess portions of the insulating material and the conductive material are removed to form the trench structures 103, as shown in FIG. 1B.

In some exemplified embodiments, the steps of removing portions of the insulating material and the conductive material may include (but not limited to) removing an excess portion of the conductive material and an excess portion of the insulating material that are above the top surface 102a of the epitaxial layer 102 by using a planarization process. The top surface 102a of the epitaxial layer 102 is exposed after the aforementioned planarization process is performed. The aforementioned planarization process is, for example, a chemical mechanical polishing (CMP) process, a mechanical polishing process, an etching process, another suitable process, or a combination of the aforementioned processes.

After the aforementioned removal step is performed, the remaining portions of the insulating material are referred to as the insulating layers 104, and the remaining portions of the conductive material are referred to as the conductive portions 105. The conductive portions 105 and the epitaxial layer 102 are separated by the insulating layers 104. In some exemplified embodiments, after the aforementioned planarization process, the conductive portion 105 is formed on the insulating layer 104 in each of the trenches. The top surfaces 105a of the conductive portions 105 and the top surfaces 104a of the insulating layers 104 are substantially coplanar with the top surface 102a of the epitaxial layer 102, as shown in FIG. 1B.

In some embodiments, the conductive portions 105 may optionally contain dopants of the first conductivity type. In this exemplified embodiment, the first conductivity type is n-type. In some embodiments, the dopants of the conductive portion 105 may include phosphorus or another suitable doping material. According to some embodiments, if the trench structures 103 are electrically connected to the gate electrodes in the subsequent process, the conductive portions 105 of the trench structures 103 can reduce the on-resistance, and the conductive portions 105 of the first conductivity type can further enhance the reduced surface electric field (RESURF) effect.

Referring to FIG. 1C, after the trench structures 103 are formed, several well regions 106 are formed in the epitaxial layer 102, in accordance with some embodiments of the present disclosure. The well regions 106 and the epitaxial layer 102 have different conductivity types, such as the second conductivity type. In this exemplified embodiment, the well regions 106 are p-type, and are similar to as p-body regions. In addition, the depth of the trench structures 103 in the epitaxial layer 102 (for example, the depth in the first direction D1) is greater than the depth of the well regions 106 in the epitaxial layer 102 (for example, the depth the first direction D1). More specifically, the bottom surfaces 103b of the trench structures 103 (i.e., the bottom surfaces 104b of the insulating layer 104) are closer to the substrate 100 than the bottom surfaces 106b of the well regions 106. In some embodiments, the doping concentration of each of the well regions 106 is in the range of about 1E16 atoms/cm³ to about 1E18 atoms/cm³. According to some embodiments, the well region 106 functions as a channel region of a semiconductor device.

In addition, one side of the well region 106 is in contact with the trench structure 103, and the other side and the bottom surface of the well region 106 are covered by the epitaxial layer 102, in accordance with some embodiments of the present disclosure. For example, the first sidewall 106s1 of one of the well regions 106 contacts the corresponding trench structure 103. In other words, after the well regions 106 are formed, the first side 103s1 (i.e., the first outer wall 104s1 of the insulating layer 104) of one of the trench structures 103 extends in the epitaxial layer 102 along the first sidewall 106s1 of the well region 106.

In some embodiments, the well regions 106 shown in FIG. 1C can be formed in the epitaxial layer 102 by doping from the top surface 102a of the epitaxial layer 102 using a deposition process, a patterning lithography process, an etching process and an implantation process. Therefore, the well regions 106 are doped downward from the top surface 102a of the epitaxial layer 102 to a certain depth of the epitaxial layer 102. In one exemplified embodiment, an oxide hard mask material layer is deposited over the top surface 102a of the epitaxial layer 102, and then a patterned photoresist (PR) is formed on the oxide hard mask material layer. The pattern of the patterned PR corresponds to the positions of the well regions 106. Then, the oxide hard mask material layer is etched by using the patterned PR to form an oxide hard mask. The patterned PR is removed, and the epitaxial layer 102 is doped through the oxide hard mask to form the well regions 106 in the epitaxial layer 102. Then, the oxide hard mask is removed. It should be noted that the cross-sectional view in FIG. 1C cannot show the three-dimensional shape of the well regions 106, but each of the well regions 106 is a doping region that extends in the first direction D1, the second direction D2 and the third direction D3.

In addition, according to some embodiments, the epitaxial portions that are outside and below the well regions 106 are collectively referred to as a drift region R_{D}, and the drift region Rp has the first conductivity type (for example, n-type). The drift region R_{D} is in contact with the second sidewalls 106s2 and the bottom surfaces 106b of the well regions 106, as shown in FIG. 1C. In this exemplified embodiment, the well regions 106 and the drift region Rp are in direct contact with the trench structures 103, such as in direct contact with the insulating layers 104. The well regions 106 and the drift region Rp are separated from the conductive portions 105 by the insulating layers 104 of the trench structures 103. Specifically, as shown in FIG. 1C, each of the first sidewalls 106s1 of the well regions 106 is in contact with the upper portion 103s1_{U} of the first side 103s1 of the corresponding trench structure 103. The drift region Rp is in contact with the lower portions 103s1_{L} of the first sides 103s1 of the trench structures 103. In the processes of some embodiments, viewed from the top of the epitaxial layer 102, a mask for defining the well regions 106 (extending in the second direction D2 and the third direction D3; not shown) and another mask for defining the trench structures 103 (extending in the second direction D2 and the third direction D3, not shown) partially overlap in the second direction D2 so that the subsequently formed well regions 106 are in contact with the first sides 103s1 of the trench structures 103.

Next, another ion implantation process can be performed on the top surfaces 106a of the well regions 106 (that is, the top surface 102a of the epitaxial layer 102) to form the first heavily doped regions 108 in the well regions 106, in accordance with some embodiments of the present disclosure. In some embodiments, one side of each of the first heavily doped portions 108 is in contact with the adjacent trench structure 103. For example, each of the first heavily doped portions 108 is in directly contact with the insulating layer of the adjacent trench structure 103.

In one exemplified embodiment, the first heavily doped portions 108 and the epitaxial layer 102 have the same conductivity type, such as the first conductivity type. In this exemplified embodiment, the first heavily doped portions 108 are n-type. In some embodiments, the doping concentration of the first heavily doped portions 108 is greater than the doping concentration of the epitaxial layer 102. In some embodiments, the doping concentration of the first heavily doped portions 108 is in the range of about 1E18 atoms/cm³ to about 1E21 atoms/cm³.

In some embodiments, the first heavily doped portions 108 can be formed in the well regions 106 by doping from the top surface 102a of the epitaxial layer 102 using a deposition process, a patterning lithography process, an etching process and an implantation process. In one exemplified embodiment, an oxide hard mask material layer (not shown) can be deposited over the top surface 102a of the epitaxial layer 102, and then a patterned photoresist that has a pattern corresponding to the positions of the first heavily doped portions is formed on the oxide hard mask material layer. The oxide hard mask material layer is etched by using the patterned PR to form an oxide hard mask. The patterned PR is removed, and the epitaxial layer 102 is doped through the oxide hard mask to form the first heavily doped portions 108 in the well regions 106. Then, the oxide hard mask is removed.

Next, referring to FIG. 1D, the planar gate structures 110 are formed on the top surface 102a of the epitaxial layer 102, and these gate structures 110 correspond to the underlying well regions 106, in accordance with some embodiments of the present disclosure. Specifically, each of the gate structures 110 is formed over the corresponding well region 106, the first heavily doped portion 108 in the well region 106 and a portion of the drift region R_{D}.

In some embodiments, each of the gate structures 110 includes a gate dielectric layer 111 and a gate electrode 112 over the gate dielectric layer 111. The gate dielectric layer may include silicon oxide or another suitable dielectric material. The gate electrode 112 may include polysilicon or another suitable conductive material. A dielectric material layer (not shown) can be formed on the epitaxial layer 102 by using a deposition process (such as a physical vapor deposition (PVD) process, a chemical vapor deposition (CVD) process, an atomic layer deposition (ALD) process) or a thermal oxidation process. Then, a conductive material (not shown) is deposited on the dielectric material layer. The deposition process may be a physical vapor deposition (PVD) process, a chemical vapor deposition (CVD) process, another suitable process, or a combination of the aforementioned processes. Next, the aforementioned dielectric material layer and the conductive material can be patterned by using a lithography process and an etching process to form the gate dielectric layer 111 and the gate electrode 112 of each of the gate structures 110.

As shown in FIG. 1D, after the gate structures 110 are formed, an interlayer dielectric (ILD) layer 113 is formed over the epitaxial layer 102, in accordance with some embodiments of the present disclosure. More specifically, the interlayer dielectric layer 113 is formed on the top surface 102a of the epitaxial layer 102 and covers the gate structures 110, the first heavily doped portions 108 and the trench structures 103.

In some embodiments, the interlayer dielectric layer 113 may be silicon oxide, or another suitable low-k dielectric material, or a combination of the aforementioned materials. In some embodiments, the material of the interlayer dielectric layer 113 is different from the material of the insulating layers 104 of the trench structures 103. In some other embodiments, the material of the interlayer dielectric layer 113 is the same as the material of the insulating layers 104 of the trench structures 103. In addition, the interlayer dielectric layer 113 can be deposited on the epitaxial layer 102 by using a deposition process. In some embodiments, the above-mentioned deposition process for forming the interlayer dielectric layer 113 can be a physical vapor deposition (PVD) process, a chemical vapor deposition (CVD) process, another suitable process, or a combination of the aforementioned processes.

Next, referring to FIG. 1E, portions of the interlayer dielectric layer 113, portions of the first heavily doped portions 108, and portions of the well regions 106 are removed to form several contact holes 114, in accordance with some embodiments of the present disclosure. Each of the bottoms 114b of the contact holes 114 exposes the corresponding well regions 106. More specifically, after the removal step, the contact holes 114 expose the first heavily doped portions 108 and the well regions 106. In addition, after the removal step, each of the contact holes 114 is positioned between the gate structure 110 and the trench structure 103.

The contact holes 114 can be formed by using a lithography patterning process and an etching process, in accordance with some embodiments of the present disclosure. In one exemplified embodiment, after an interlayer dielectric material (not shown) is deposited over the epitaxial layer 102, one or more etching processes can be performed to remove portions of the interlayer dielectric layer 113, portions of the first heavily doped portions 108 and portions of the well regions 106 to form the contact holes 114. In some embodiments that the patterned photoresist is used as a mask, the aforementioned lithographic patterning process includes photoresist coating (e.g., spin-on coating), soft baking, mask alignment, exposure, post-exposure baking, developing the photoresist, rinsing and drying (e.g., hard baking), another suitable process or a combination of the aforementioned processes. In addition, in some embodiments, the aforementioned etching process includes a dry etching process, a wet etching process, a plasma etching process, a reactive ion etching process, another suitable process, or a combination of the aforementioned processes.

After the contact holes 114 are formed, the remaining portions of the first heavily doped portions 108 each in the corresponding well regions 106 can be referred to as source regions of a semiconductor device, in accordance with some embodiments of the present disclosure.

It should be noted that, in some embodiments, as shown in FIG. 1E, each of the contact holes 114 also exposes the insulating layer 104 of the adjacent trench structure 103. Accordingly, in this exemplified embodiment, no portion of the first heavily doped portion is disposed between the contact holes 114 and the trench structures 103 (in the second direction D2). However, the present disclosure is not limited thereto. In some other embodiments, the contact hole 114 can also be separated from the adjacent trench structure by a distance (not shown). That is, there is a portion of the first heavily doped portion between the contact hole 114 and the adjacent trench structure 103 (in the second direction D2). In a conventional semiconductor device, the vertical conductive trench is separated from the well region (such as a p-type body region) by a distance; that is, there is an epitaxial portion (in the second direction D2) between the vertical conductive trench and the well region (in the second direction D2). Compared to the conventional semiconductor device, whether the contact hole 114 exposes the adjacent trench structure 103 or is separated from the trench structure 103, in accordance with some semiconductor devices of the embodiments, the contact hole 114 of the embodiments is positioned between the gate structure 110 and the trench structure 103, the well region 106 is adjacent to the trench structure 103 and the drift region Rp is outside the well region 106, so no epitaxial portion of the drift region Rp is between the contact hole 114 and the trench structure 103 (in the second direction D2).

Next, still referring to FIG. 1E, the second heavily doped portions 115 can be formed in the well regions 106 through the bottom portions of the contact holes 114 (such as the bottom surfaces 114b and portions of the sidewalls of the contact holes 114) by using an implantation process, in accordance with some embodiments of the present disclosure. In some embodiments, the second heavily doped portions 115 each are disposed around the bottom portions of the contact holes 114. Those second heavily doped portions 115 are positioned adjacent to the corresponding trench structures 103 and the first heavily doped portions 108. For example, the second heavily doped portions 115 are positioned under the first heavily doped portions 108. In this exemplified embodiment, one side of each of the second heavily doped portions 115 is in contact (such as in physical contact) with the adjacent trench structure 103. For example, each of the second heavily doped portions 115 is in direct contact with the insulating layer 104 of the adjacent trench structure 103, as shown in FIG. 1E.

In addition, in some embodiments, the second heavily doped portions 115 and the well region 106 have the same conductivity type, such as the second conductivity type. In this exemplified embodiment, the second heavily doped portions 115 are p-type. In some embodiments, the doping concentration of the second heavily doped portions 115 is greater than the doping concentration of the well regions 106. In some embodiments, the doping concentration of the second heavily doped portions 115 is in the range of about 1E18 atoms/cm³ to about 1E21 atoms/cm³. In a semiconductor device, good ohmic contact between the well regions and the subsequently formed contact plugs 116 (FIG. 1F) in the contact holes can be achieved by forming the second heavily doped portions 115, in accordance with some embodiments of the present disclosure.

Next, referring to FIG. 1F, several contact plugs 116 are formed in the contact holes 114, in accordance with some embodiments of the present disclosure. Each of the contact plugs 116 is positioned between the gate structure 110 and the trench structure 103 in the second direction D2. In addition, the bottoms of the contact plugs 116 are in contact with the second heavily doped portions 115. That is, the bottom portion of each of the contact plugs 116 is surrounded and covered by the second heavily doped portion 115.

In addition, the contact plugs 116 are in direct contact with the adjacent trench structure 103, in accordance with some embodiments of the present disclosure. In some other embodiments, each of the contact plugs 116 can be separated from the adjacent trench structure 103. In this exemplified embodiment, there is no epitaxial portion of the drift region Rp disposed between the contact plug 116 and the adjacent trench structure 103 in the second direction D2.

In addition, according to some embodiments, each of the contact plugs 116 is electrically connected to the corresponding well region 106. Each of the contact plugs 116 is also electrically connected to the corresponding first heavily doped portion 108. In this exemplified embodiment, better electrical connection between the contact plugs 116 and the well regions 106 can be achieved through the second heavily doped portions 115. In addition, each of the contact plugs 116 and the adjacent gate structure 110 are separated from each other, in accordance with some embodiments of the present disclosure. For example, there is a distance between the contact plug 116 and the adjacent gate structure 110 in the lateral direction (such as in the second direction D2). In an embodiment where the first heavily doped portions 108 are used as the source regions of the semiconductor device 10, the contact plugs 116 can be referred to as source contacts.

In some embodiments, each of the contact plugs 116 includes a contact barrier layer 117 and a contact conductive layer 118. The contact barrier layer 117 is formed on the sidewall and the bottom portion of the contact hole 114 as a barrier liner. The contact conductive layer 118 fills up the remaining space in the contact hole 114. In this exemplified embodiment, the top surfaces of the contact plugs 116 (including the top surfaces of the contact barrier layers 117 and the top surfaces of the contact conductive layers 118) are substantially level with the top surface of the interlayer dielectric layer 113, as shown in FIG. 1F.

In some exemplified embodiments, a barrier material (not shown) can be formed on the interlayer dielectric layer 113 by using a deposition process, and the barrier material is isotropically deposited in the contact holes 114. Then, a conductive material (not shown) is deposited on the barrier material layer, and the conductive material fills up the remaining space in the contact holes 114. Next, in some embodiments, the excess portions of the conductive material and barrier material that are above the top surface of the interlayer dielectric layer 113 are removed, such as by etching or another suitable method, to form the contact barrier layers 117 and the contact conductive layers 118 in the contact holes 114.

In some embodiments, the material of the contact barrier layers 117 includes titanium (Ti), titanium nitride (TiN), tantalum (Ta), tantalum nitride (TaN), cobalt (Co), cobalt tungsten phosphorus compound (CoWP), ruthenium (Ru), aluminum oxide (Al₂O₃), magnesium oxide (MgO), aluminum nitride (AlN), tantalum pentoxide (Ta₂O₅), silicon dioxide (SiO₂), hafnium dioxide (HfO₂), zirconium dioxide (ZrO₂), magnesium fluoride (MgF₂), calcium fluoride (CaF₂), another suitable barrier material, or a combination of the aforementioned materials. In some embodiments, the contact barrier layers 117 can be formed by a chemical vapor deposition (CVD) process, an atomic layer deposition (ALD) process, a physical vapor deposition (PVD) process, another suitable process, or a combination of the foregoing processes.

In some embodiments, the contact conductive layer 118 is a single-layer structure or a multilayer structure that includes one or more conductive materials. In some embodiments, the material of the contact conductive layers 118 includes tungsten (W), aluminum (Al), copper (Cu), titanium (Ti), tantalum (Ta), titanium nitride (TiN), tantalum nitride (TaN), nickel silicide (NiSi), cobalt silicide (CoSi), tantalum carbide (TaC), tantalum silicon nitride (TaSiN), tantalum carbide nitride (TaCN), titanium aluminide (TiAl), titanium aluminide nitride (TiAIN), another suitable metal, or a combination of the foregoing materials. In addition, the aforementioned conductive material can be formed by using a chemical vapor deposition (CVD) process, an atomic layer deposition (ALD) process, a physical vapor deposition (PVD) process, another suitable process, or a combination of the foregoing processes, in accordance with some embodiments of the present disclosure.

Next, after the contact plugs 116 are formed, the subsequent processes for forming other components are performed. According to some embodiments, a metal layer (not shown) is formed over the interlayer dielectric layer 113 and the contact plugs 116. The metal layer covers the contact plugs 116 and is in physical and electrical contact with the contact plug 116. Therefore, the metal layer is electrically connected to the first heavily doped portions 108, the second heavily doped portions 115 and the well regions 106 through the contact plugs 116, in accordance with some embodiments of the present disclosure.

In some embodiments, the metal layer includes copper, silver, gold, aluminum, tungsten, another suitable metal material, or a combination of the aforementioned materials. In some embodiments, the metal layer and the contact plug 116 are formed of the same material(s). In some other embodiments, the material of the metal layer is different from the material of the contact plug 116. The metal layer can be formed on the contact plugs 116 by a deposition process, in accordance with some embodiments of the present disclosure. The deposition process may include a physical vapor deposition (PVD) process, a chemical vapor deposition (CVD) process, another suitable process, or a combination of the foregoing processes. In some embodiments, after the metal layer is formed, the fabrication of a semiconductor device 10 is completed.

The metal layer can be used as a top metal of the semiconductor device for electrically connecting to the heavily doped regions 108 that are the source regions of the semiconductor device, in accordance with some embodiments of the present disclosure. Thus, the metal layer can also be referred to as a source metal layer.

According to some embodiments, in the semiconductor device shown in FIG. 1F, the components of each of the two cells are arranged in an asymmetric configuration. The area of one cell are similar to an area defined by a cell pitch CPH1 in FIG. 1F. In one of the cells, the well region 103, the first heavily doped portion 108, the second heavily doped portion 115, the gate structure 110 and the contact plug 116 are formed at one side of the trench structure 103, in accordance with some embodiments of the present disclosure. There is only the drift region Rp on the opposite side of the trench structure 103. More specifically, in some embodiments, the upper portion of the first side 103s1 of the trench structure 103 is in contact with the components of the second conductivity type (such as the well region 106 and the heavily doped portion 115)(for example, p-type). The lower portion of the first side 103s1 is in contact with the component (such as the drift region Rp) of the first conductivity type (for example, n-type), as shown in FIG. 1F. In addition, the second side 103s2 of the trench structure 103 of one cell is only in contact with the component of the first conductivity type (for example, n-type)(such as the drift region R_{D}), and is not in contact with any component of the second conductivity type (for example, p-type).

However, the present disclosure is not limited to the exemplified asymmetric configuration of the cells as described above. One or more cells that include components arranged in a symmetric configuration can be provided to improve the electrical performance of the semiconductor device, in accordance with some other embodiments of the present disclosure.

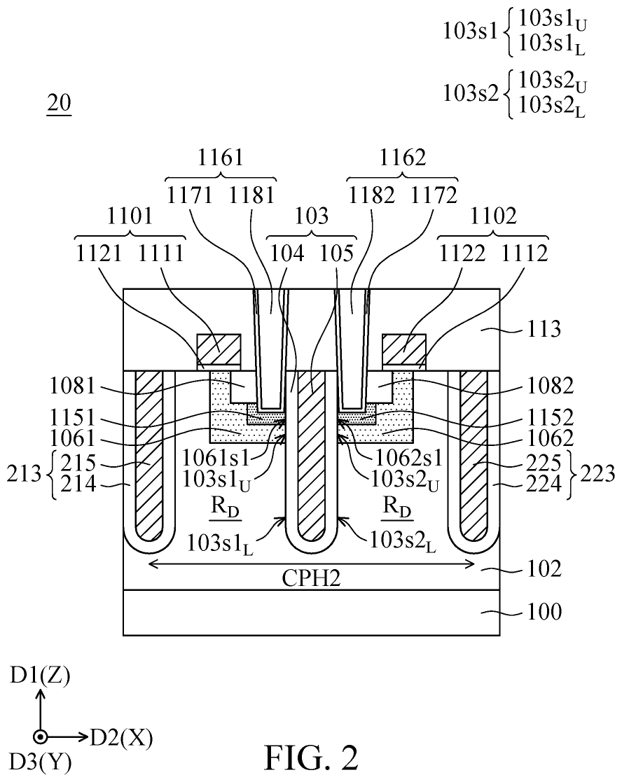

FIG. 2 is a cross-sectional view of an intermediate stage of a semiconductor device 20, in accordance with some embodiments of the present disclosure. As shown in FIG. 2, the components of a cell are arranged in an asymmetric configuration. For example, in a cell that is defined by an area with the cell pitch CPH2, the opposite sides of the trench structure 103 have the well regions, the heavily doped portions, the gate structures and the contact plugs that are arranged symmetrically. In addition, the features/components in FIG. 2 similar or identical to the features/components in FIG. 1 are designated with similar or the same reference numbers, and the details of those similar or the identical features/components are similar to the related contents in the aforementioned descriptions.

Referring to FIG. 2, a semiconductor material is epitaxially grown on a substrate 100 of the first conductivity type (such, n-type) to form an epitaxial layer 102, in accordance with some embodiments of the present disclosure. The semiconductor material and the substrate 100 have the same conductivity type (such as n-type). Details of the configurations, the materials and the manufacturing methods of the substrate 100 and the epitaxial layer 102 are similar to the above-mentioned descriptions referring to FIG. 1A, and they will not be repeated here.

Next, several trench structures 103, 213 and 223 are formed in the epitaxial layer 102, in accordance with some embodiments of the present disclosure. The trench structure includes an insulating layer 104 and a conductive portion 105. As shown in FIG. 2, the insulating layer 104 covers the sidewall 105s and the bottom 105b of the conductive portion 105. Details of the configuration, the material and the manufacturing method of the trench structure 103 are similar to the above-mentioned descriptions referring to FIG. 1B, and they will not be repeated here.

Similarly, the trench structure 213 includes an insulating layer 214 and a conductive portion 215. As shown in FIG. 2, the insulating layer 214 covers the sidewall and the bottom portion of the conductive portion 215. The trench structure 223 includes an insulating layer 224 and a conductive portion 225. The insulating layer 224 covers the sidewall and the bottom portion of the conductive portion 225. Details of the configurations, the materials and the manufacturing methods of the trench structure 213 and the trench structure 223 are similar to the above-mentioned descriptions of the trench structure 103 in FIG. 1B, and they will not be repeated here.

After forming the trench structures 103, 213 and 223, the first well region 1061 and the second well region 1062 are formed in the epitaxial layer 102. The first well region 1061 and the second well region 1062 extend downward from the top surface 102a of the epitaxial layer 102 into the epitaxial layer 102, in accordance with some embodiments of the present disclosure. As shown in FIG. 2, the first well region 1061 is adjacent to the first side 103s1 of the trench structure 103, and the second well region 1062 is adjacent to the second side 103s2 of the trench structure 103. The second side 103s2 is opposite the first side 103s1. In addition, the first well region 1061 and the second well region 1062 have a conductivity type that is different from the conductivity type of the epitaxial layer 102, such as the second conductivity type. In this exemplified embodiment, the first well region 1061 and the second well region 1062 are p-type. The first well region 1061 and the second well region 1062 can also be referred to as p-type body regions. In addition, the depth of the trench structure 103 in the epitaxial layer 102 (such as in the first direction D1) is greater than the depths of the first well region 1061 and the second well region 1062 in the epitaxial layer 102 (such as in the first direction D1). In some embodiments, the doping concentration of the first well region 1061 and the second well region 1062 is in the range of about 1E16 atoms/cm³ to about 1E18 atoms/cm³.

In addition, one side of each of the well regions is in contact with the trench structure 103, and the other side and the bottom portion of the well region are covered by a portion of the epitaxial layer 102, in accordance with some embodiments of the present disclosure. For example, the first sidewall 1061s1 of the first well region 1061 is in contact with the first side 103s1 of the trench structure 103, and the first sidewall 1062s1 of the second well region 1062 is in contact with the second side 103s2 of the trench structure 103. According to one of the intermediate stages of the fabrication, in some embodiments, after the first well region 1061 and the second well region 1062 are formed, the first side 103s1 of the trench structure 103 extends in the epitaxial layer 102 along the first sidewall 106s1 of the first well region 1061. Similarly, in some embodiments, the second side 103s2 of the trench structure 103 extends in the epitaxial layer 102 along the first sidewall 1062s1 of the second well region 1062.

In addition, in this exemplified embodiment, the first well region 1061 is in direct contact with the upper portion of the first side 103s1 of the trench structure 103 (such as in direct contact with the insulating layer 104). The drift region Rp is in direct contact with the lower portion of the first side 103s1 of the trench structure 103 (such as in direct contact with the insulating layer 104). Similarly, the second well region 1062 and the drift region R_{D} are in direct contact with the upper portion and the lower portion of the second side 103s2 of the trench structure 103 (they are in direct contact with the insulating layer 104), respectively. Therefore, the opposite sides such as the first side 103s1 and the second side 103s2 of the trench structure 103 are in contact with the well region of the second conductivity type (for example, p-type) and the drift region Rp of the first conductivity type (for example, n-type), respectively.

Details of the configurations, the materials and the manufacturing methods of the above-mentioned first well region 1061 and the second well region 1062 are similar to the above-mentioned descriptions of the well region 106 in FIG. 1C, and will not be repeated here.

Next, in some embodiments, the first heavily doped portion 1081 and the third heavily doped portion 1082 can be formed in the first well region 1061 and the second well region 1062 by doping from the top surface 102a of the epitaxial layer 102 using a deposition process, a patterning lithography process, an etching process and an implantation process. One side of the first heavily doped portion 1081 is in contact with the first side 103s1 of the adjacent trench structure 103, in accordance with some embodiments of the present disclosure. One side of the third heavily doped portion 1082 is in contact with the second side 103s2 of the adjacent trench structure 103. In addition, the first heavily doped portion 1081 and the third heavily doped portion 1082 are separated from the conductive portion 105 of the trench structure 103 by the insulating layer 104 of the trench structure 103.

In one exemplified embodiment, the first heavily doped portion 1081, the third heavily doped portion 1082 and the epitaxial layer 102 have the same conductivity type, such as the first conductivity type. In this exemplified embodiment, the first heavily doped portion and the third heavily doped portion 1082 are n-type. In some embodiments, the doping concentration of the first heavily doped portion 1081 and the third heavily doped portion is greater than the doping concentration of the epitaxial layer 102. In some embodiments, the doping concentration of the first heavily doped portion 1081 and the third heavily doped portion 1082 is in the range of about 1E18 atoms/cm³ to about 1E21 atoms/cm³.

Details of the configurations, the materials and the manufacturing methods of the first heavily doped portion 1081 and the third heavily doped portion 1082 are similar to the above-mentioned descriptions of the first heavily doped portion 108 in FIG. 1C, and they will not be repeated here.

Next, referring to FIG. 1D, a first gate structure 1101 and a second gate structure 1102 that are planar gate structure are formed on the top surface 102a of the epitaxial layer 102, in accordance with some embodiments of the present disclosure. As shown in FIG. 1D, the first gate structure 1101 corresponds to the underlying first well region 1061, and the second gate structure 1102 corresponds to the underlying second well region 1062. More specifically, in this exemplified embodiment, the first gate structure 1101 is formed over the first well region 1061, the first heavily doped portion 1081 and a portion of the drift region R_{D}. Similarly, the second gate structure 1102 is formed over the second well region 1062, the third heavily doped portion 1082 and a portion of the drift region R_{D}.

In some embodiments, the first gate structure 1101 includes a first gate dielectric layer 1111 and a first gate electrode 1121 that is formed on the first gate dielectric layer 1111. The second gate structure 1102 includes a second gate dielectric layer 1112 and a second gate electrode 1122 that is formed on the second gate dielectric layer 1112. Details of the configurations, the materials and the manufacturing methods of the first gate structure 1101 and the second gate structure 1102 are similar to the above-mentioned descriptions of the gate structure 110 in FIG. 1D, and they will not be repeated here.

After the first gate structure 1101 and the second gate structure 1102 are formed, an interlayer dielectric (ILD) layer 113 is formed over the epitaxial layer 102, in accordance with some embodiments of the present disclosure. More specifically, the interlayer dielectric layer 113 is formed on the top surface 102a of the epitaxial layer 102. The interlayer dielectric layer 113 covers the first gate structure 1101, the second gate structure 1102, the first heavily doped portion 1081, the third heavily doped portion 1082 and the trench structures 103, 213 and 223. Details of the configurations, the materials and the manufacturing methods of the above-mentioned interlayer dielectric layer 113 are similar to the above-mentioned descriptions of the interlayer dielectric layer 113, and they will not be repeated here.

Next, in some embodiments, a contact hole is formed on one of the opposite sides of the trench structure 103. The contact holes are formed corresponding to the first heavily doped portion 1081 and the third heavily doped portion 1082. For example, a portion of the interlayer dielectric layer 113, a portion of the first heavily doped portion 1081 and a portion of the first well region 1061 are removed, so that a first contact hole (not shown) is formed between the first gate structure 1101 and the trench structure 103. The bottom portion of the first contact hole exposes the first well region 1061. In addition, a portion of the interlayer dielectric layer 113, a portion of the third heavily doped portion 1082, and a portion of the second well region 1062 are simultaneously removed, so that a second contact hole (not shown) is formed between the second gate structure 1102 and the trench structure 103. Similarly, the bottom portion of the second contact hole exposes the second well region 1062.

According to a semiconductor device of some embodiments of the present disclosure, after the first contact hole and the second contact hole are formed, the remaining portion of the first heavily doped portion 1081 and the remaining portion of the third heavily doped portion 1082 can be referred to as source regions of a symmetrical semiconductor device. Details of the configurations, the materials and the manufacturing methods of the first contact hole and the second contact hole can also be referred to the above-mentioned description of the contact hole 114 in FIG. 1E, and they will not be repeated here.

Next, a second heavily doped portion 1151 is formed in the first well region 1061 and a fourth heavily doped portion 1152 is formed in the second well region 1062 by using an implantation process, in accordance with some embodiments of the present disclosure. The ion implantation process can be performed through the bottoms of the first contact hole and the second contact hole. In some embodiments, the second heavily doped portion 1151 is disposed around the bottom portion of the first contact hole. The second heavily doped portion 1151 is positioned adjacent to the trench structure 103 and the first heavily doped portion 1081 (for example, the second heavily doped portion 1151 is formed under the first heavily doped portion 1081). Similarly, the fourth heavily doped portion 1152 is disposed around the bottom portion of the second contact hole. The fourth heavily doped portion 1152 is positioned adjacent to the trench structure 103 and the third heavily doped portion 1082 (for example, the fourth heavily doped portion 1152 is formed under the third heavily doped portion 1082). In this exemplified embodiment, the second heavily doped portion 1151 is in physical contact with the first side 103s1 of the adjacent trench structure 103. The fourth heavily doped portion 1152 is in physical contact with the second side 103s2 of the adjacent trench structure 103. For example, the second heavily doped portion 1151 and the fourth heavily doped portion 1152 are in direct contact with the insulating layer 104 of the trench structure 103.

In addition, in some embodiments, the second heavily doped portion 1151, the fourth heavily doped portion 1152 and the well region 106 have the same conductivity type, such as the second conductivity type. For example, the second heavily doped portion 1151 and the fourth heavily doped portion 1152 are p-type. In some embodiments, the doping concentration of the second heavily doped portion 1151 is greater than the doping concentration of the first well region 1061. The doping concentration of the fourth heavily doped portion 1152 is greater than the doping concentration of the second well region 1062. In addition, in some embodiments, the doping concentration of the second heavily doped portion 1151 and the fourth heavily doped portion 1152 are in the range of about 1E18 atoms/cm³ to about 1E21 atoms/cm³. In a semiconductor device, good ohmic contact between the well regions and the subsequently formed contact plugs can be achieved by forming the second heavily doped portion 1151 and the fourth heavily doped portion 1152, in accordance with some embodiments of the present disclosure.

Details of the configurations, the materials and the manufacturing methods of the second heavily doped portion 1151 and the fourth heavily doped portion 1152 are similar to the above-mentioned second heavily doped portion 115 in FIG. 1E, and they will not be repeated here.

Next, several contact plugs are formed in the contact holes, in accordance with some embodiments of the present disclosure. For example, a first contact plug 1161 is formed in the first contact hole and a second contact plug 1162 is formed in the second contact hole. The first contact plug 1161 is positioned between the first gate structure 1101 and the trench structure 103 in the second direction D2. The second contact plug 1162 is positioned between the second gate structure 1102 and the trench structure 103 in the second direction D2. In this exemplified embodiment, the bottom portion of the first contact plug 1161 is in contact with the second heavily doped portion 1151, and the bottom portion of the second contact plug 1162 is in contact with the fourth heavily doped portion 1152. In addition, in this embodiment, no epitaxial portion of the drift region Rp is disposed between the first contact plug 1161 and the trench structure 103 (in the second direction). Similarly, there is no epitaxial portion of the drift region R_{D} disposed between the second contact plug 1162 and the trench structure 103 (in the second direction).

In some embodiments, the first contact plug 1161 includes a first contact barrier layer 1171 and a first contact conductive layer 1181. The first contact barrier layer 1171 is formed on the sidewall and the bottom portion of first the contact hole as a barrier liner. The first contact conductive layer 1181 fills up the remaining space in the first contact hole. The second contact plug 1162 includes a second contact barrier layer 1172 and a second contact conductive layer 1182. The second contact barrier layer 1172 is formed on the sidewall and the bottom portion of the second contact hole as a barrier liner. The second contact conductive layer 1182 fills up the remaining space in the second contact hole.

In addition, in some embodiments, the first contact plug 1161 is electrically connected to the first well region 1061 and the first heavily doped portion 1081. The second contact plug 1162 is electrically connected to the second well region 1062 and the second heavily doped portion 1082. In the example where the first heavily doped portion 1081 and the second heavily doped portion 1082 function as the source regions of the semiconductor device, the first contact plug 1161 and the second contact plug 1162 are similar to as the first source contact and the second source contact, respectively.

For details of the configurations, the materials and the manufacturing methods of the first contact plug 1161 and the second contact plug 1162, refer to the above-mentioned contact plug 116 in FIG. 1F, the description of which will not be repeated here.

According to some embodiments, in the semiconductor device shown in FIG. 2, the first well region 1061, the first gate structure 1101, the first heavily doped portion 1081, the second heavily doped portion 1151 and the first contact plug 1161 are positioned on the same side of the trench structure 103. The second well region 1062, the second gate structure 1102, the third heavily doped portion 1082, the fourth heavily doped portion 1152 and the second contact plug 1162 are positioned on the other side of the trench structure 103. If the trench structure 103 is regarded as a center of symmetry, the components that are disposed on opposite sides of the trench structure 103 are arranged in a symmetric configuration. Those aforementioned components that are disposed in an area defined by a cell pitch CPH2 constitute a symmetric cell, in accordance with some embodiments of the present disclosure.

Whether the components of a semiconductor device are arranged in an asymmetric configuration of some embodiments (as shown in FIG. 1F) or arranged in a symmetrical configuration of some embodiments (as shown in FIG. 2), the electrical performance of the semiconductor devices in the embodiments can be improved.

It should be noted that although one cell in the semiconductor device shown in FIG. 2 includes two channels, the cell pitch CPH2 shown in FIG. 2 is twice the cell pitch CPH 1 shown in FIG. 1. Therefore, the two types of the cells (FIG. 1 and FIG. 2) in the semiconductor devices have the same electrical performance in terms of the characteristic on-resistance.

In addition, according to some embodiments of the present disclosure, whether the components of a semiconductor device are arranged in an asymmetric configuration of some embodiments (as shown in FIG. 1F) or the components of a semiconductor device are arranged in a symmetrical configuration of some other embodiments (as shown in FIG. 2), the conductive portions 105 of the trench structures 103 can be electrically connected to the gate structures 110. The conductive portion 105 of the trench structures 103 can be electrically connected to the gate electrode 112 through the interconnections (not shown) in the semiconductor device. Alternatively, the conductive portion 105 of the trench structures 103 can be electrically connected to the gate electrode 112 through pins that are provided on the conductive portion 105, and then the electrical connection to the gate structure 110 can be completed by wire bonding during the packaging stage.

In addition, according to some embodiments of the present disclosure, whether the components of a semiconductor device are arranged in an asymmetric configuration of some embodiments (as shown in FIG. 1F) or the components of a semiconductor device are arranged in a symmetrical configuration of some other embodiments (as shown in FIG. 2), the conductive portions 105 of the trench structures 103 can be electrically connected to a source terminal. For example, the conductive portion 105 of the trench structures 103 can be electrically connected to the first heavily doped portion 108 (source region) and the contact plug 116 (source contact) through the interconnections (not shown) in the semiconductor device. Alternatively, the conductive portion 105 of the trench structures 103 can be electrically connected to the first heavily doped portion 108 (source region) and the contact plug 116 (source contact) through pins that are coupled to the conductive portion 105, and then the electrical connection to the first heavily doped portion 108 and the contact plug 116 can be completed by wire bonding during the packaging stage.

In addition, according to some embodiments of the present disclosure, whether the components of a semiconductor device are arranged in an asymmetric configuration of some embodiments (as shown in FIG. 1F) or the components of a semiconductor device are arranged in a symmetrical configuration of some other embodiments (as shown in FIG. 2), the semiconductor devices of the embodiments are applicable to the circuit systems that are required for low-frequency operation or high-frequency operation through suitable circuit connection. For example, in some embodiments that the conductive portion 105 of the trench structure 103 is electrically connected to the gate structure 110, it generates a relatively high gate-to-drain capacitance (Cgd), but it has a relatively low on-resistance. Accordingly, the semiconductor device that has an electrical connection between the conductive portion 105 and the gate structure 110 is generally suitable for the application of the circuit system that is designed for low frequency operation. In some other embodiments that the conductive portion 105 of the trench structure 103 is electrically connected to the source terminal, it generates a relatively high on-resistance, but it has a relatively low gate-to-drain capacitance (Cgd). Accordingly, the semiconductor device that has an electrical connection between the conductive portion 105 and the source terminal is generally suitable for the application of the circuit system that is designed for high frequency operation.

In addition, a semiconductor structure may include several cells that are arranged in a parallel electrical connection, in accordance with some embodiments of the present disclosure. In some embodiments, the conductive portions 105 of the trench structures 103 of all these cells can be electrically connected to the source terminal or the gate structures 110. In some other embodiments, some conductive portions 105 of the trench structures 103 of those cells are electrically connected to the source terminal, and the remaining conductive portions 105 of the trench structure 103 are electrically connected to the gate structures 110. Accordingly, the semiconductor devices of the embodiments can be selectively configured and flexibly designed depending on the practical requirements of the application.

In addition, several relative electrical simulations are conducted for investigate the electrical characteristics of the conventional semiconductor devices and semiconductor devices of some embodiments. According to the simulation results, it can be proved that the semiconductor devices of the embodiments do have effectively improved performance on the electrical characteristics. The electrical simulations are described below.

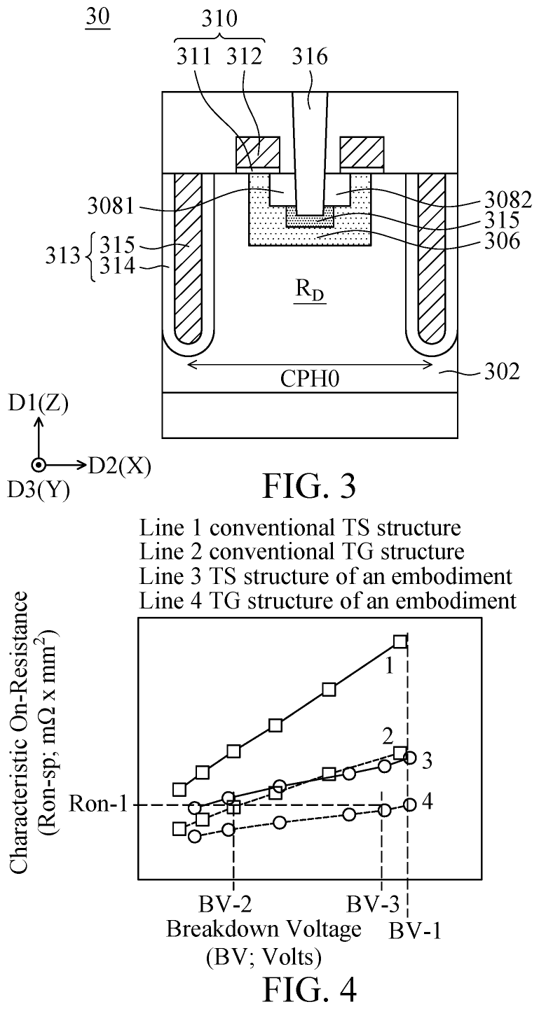

FIG. 3 is a cross-sectional view of a conventional semiconductor device. The features/components in FIG. 3 similar or identical to the features/components in FIG. 1F and FIG. 2 are designated with similar or the same reference numbers, and the details of those similar or the identical features/components can be inferred by analogy with the related contents in the aforementioned descriptions.

In the semiconductor device 30 shown in FIG. 3, several trench structures 313 are formed in the epitaxial layer 302 that is grown on the substrate 300. In this conventional semiconductor device 30, a cell that has an area defined by the cell pitch CPH0 includes two adjacent trench structures 313 and a well region 306 is disposed between the two adjacent trench structures 313. The well region 306 is surrounded by a drift region R_{D}. More specifically, the bottom and two sides of the well region 306 are surrounded by the drift region R_{D}. The drift region Rp extends between the well region 306 and adjacent trench structures 313 in the second direction D2. In addition, the semiconductor device 30 includes two gate electrodes 310 over the well region 306, and each of the gate electrodes 310 includes a gate dielectric layer 311 and a gate electrode layer 312. The semiconductor device 30 further includes a contact plug 316 between the gate electrodes 310, a first heavily doped portion 1081 and the third heavily doped part 1082 (with the first conductivity type, such as n-type) on both sides of the contact plug 316, and a second heavily doped part 315 (with the second conductivity type, such as p-type) at the bottom portion of the contact plug 316. The first heavily doped portion 1081 and the third heavily doped part 1082 function as source regions of the semiconductor device 30. The trench structure 313 can be electrically connected to the gate structure 310 (and the trench structure 313 are collectively referred to as a field plate structure), or can be electrically connected to the source regions (i.e. the first heavily doped portion 1081 and the third heavily doped portion 1082). Details of the configurations, the materials and the manufacturing methods of the components in FIG. 3 are similar to the above-mentioned descriptions referring to FIG. 1A to FIG. 1F, and they will not be repeated here.

In these simulation experiments, several electrical simulation tests were performed on the semiconductor device of the embodiments shown in FIG. 1F and the conventional semiconductor device shown in FIG. 3.

### <Static Characteristic Simulations>

First, static characteristic simulations were performed on the conventional semiconductor device and the semiconductor device of the embodiment. FIG. 4 is a simulation result that shows the characteristic on-resistance (Ron-sp; mΩ×mm²) of each of the semiconductor devices at different breakdown voltages. In addition, FIG. 4 shows the relationships between the figure of merit (Baliga's Figure-of-Merit; BFOM and the characteristic on-resistance (Ron-sp) of the semiconductor devices. Baliga's Figure-of-Merit (BFOM) are generally used to evaluate the performance of the semiconductor devices.

In FIG. 4, line 1 represents the relationships between the breakdown voltages and the characteristic on-resistances when the trench structures of a conventional semiconductor device are electrically connected to the source electrode. This conventional semiconductor device (line 1) are similar to a tie-to-source (TS) structure, and can be abbreviated as a conventional TS structure.

In FIG. 4, line 2 represents the relationships between the breakdown voltages and the characteristic on-resistances when the trench structures of a conventional semiconductor device are electrically connected to the gate electrodes. This conventional semiconductor device (line 2) are similar to a tie-to-gate (TG) structure, and can be abbreviated as a conventional TG structure.

In FIG. 4, line 3 represents the relationships between the breakdown voltages and the characteristic on-resistances when the trench structures of a semiconductor device of the embodiment are electrically connected to the source electrode. This semiconductor device of the embodiment (line 3) are similar to a tie-to-source (TS) structure, and can be abbreviated as a TS structure of the embodiment.

In FIG. 4, line 4 represents the relationships between the breakdown voltages and the characteristic on-resistances when the trench structures of a semiconductor device of the embodiment are electrically connected to the gate electrodes. This semiconductor device of the embodiment (line 4) are similar to a tie-to-gate (TG) structure, and can be abbreviated as a TG structure of the embodiment.

According to the simulation results in FIG. 4, the slope of line 2 (regarding to the conventional TG structure) is gentler than the slope of line 1 (regarding to the conventional TS structure). In addition, the simulation results show that the slope of line 4 (regarding to the TG structure of the embodiment) is gentler than the slope of line 3 (regarding to the TS structure of the embodiment). Therefore, whether the semiconductor devices have lower breakdown voltages or have higher breakdown voltages, the conventional TG structure has a lower characteristic on-resistance than the conventional TS structure. Similarly, the characteristic on-resistance of the TG structure of the embodiment is lower than the characteristic on-resistance of the TS structure of the embodiment. These simulation results show that whether it is the conventional semiconductor devices or the semiconductor devices of the embodiments, when the trench structure is electrically connected to the gate electrode (tie-to-gate; TG), there is a better trade-off electronic characteristic between the breakdown voltage and the on-resistance of the semiconductor device.

In addition, according to the simulation results in FIG. 4, at the same breakdown voltage, the characteristic on-resistance of the TS structure of the embodiment (represented by line 3) is less than the characteristic on-resistance of the conventional TS structure (represented by line 1). In one of the exemplified simulation results, compared to the characteristic on-resistance of the conventional TS structure (represented by line 1), the characteristic on-resistance of the TS structure of the embodiment (represented by line 3) is reduced by about 29% at the same breakdown voltage of BV-1.

In addition, according to the simulation results in FIG. 4, at the same breakdown voltage, the characteristic on-resistance of the TG structure of the embodiment (represented by line 4) is less than the characteristic on-resistance of the conventional TG structure (represented by line 2). In one of the exemplified simulation results, compared to the characteristic on-resistance of the conventional TG structure (represented by line 2), the characteristic on-resistance of the TG structure of the embodiment (represented by line 4) is reduced by about 18% at the same breakdown voltage of BV-1.

In addition, according to the simulation results in FIG. 4, at the same characteristic on-resistance, the breakdown voltage of the TG structure of the embodiment (represented by line 4) is higher than the breakdown voltage of the conventional TG structure (represented by line 2). In one of the exemplified simulation results, compared to the breakdown voltage BV-2 of the conventional TG structure (represented by line 2) at the characteristic on-resistance Ron-1, the breakdown voltage BV-3 of the TG structure of the embodiment (represented by line 4) at the characteristic on-resistance Ron-1 increases about 52%.

In addition, it should be noted that the on-resistance of the conventional TG structure (represented by line 2) is significantly lower than the on-resistance of the on-resistance of the conventional TS structure (represented by line 1), in accordance with the simulation results in FIG. 4. However, the conventional TG structure will sacrifice the dynamic switching energy loss because the gate-to-drain capacitance (Cgd) of the conventional TG structure is much greater than the gate-to-drain capacitance (Cgd) the conventional TS structure. According to the simulation results in FIG. 4, it is noted that the slope of line 3 (regarding to the TS structure of the embodiment) is similar to the slope of line 2 (regarding to the conventional TG structure). That is, the TS structure of the embodiment and the conventional TG structure have similar relationship between the breakdown voltage and the on-resistance. According to the forgoing discussions, the TS structure of the embodiment and the conventional TG structure have similar static characteristics.

Beside static characteristic simulations, dynamic characteristic simulations are performed on a TS structure of the embodiment and a conventional TG structure both having similar static characteristics. The results show the difference of dynamic characteristics between the TS structure of the embodiment and the conventional TG structure.

### <Dynamic Characteristic Simulations>

Dynamic characteristic simulations were performed on a conventional TG structure and a TS structure of the embodiment when the device switches between the on state and the off state. For example, according to some simulation results, compared to the gate-to-drain capacitance (Cgd) of the conventional TG structure, the gate-to-drain capacitance (Cgd) of the TS structure of the embodiment can be greatly reduced by about 96% at the same characteristic on-resistance (for example, at about 4.43 to 4.35 mΩ×mm²). Therefore, compared to the conventional TG structure, the high frequency figure of merit (HF-FOM; that is, the product of Cgd and on-resistance) of the TS structure of the embodiment is also greatly improved by about 96%.

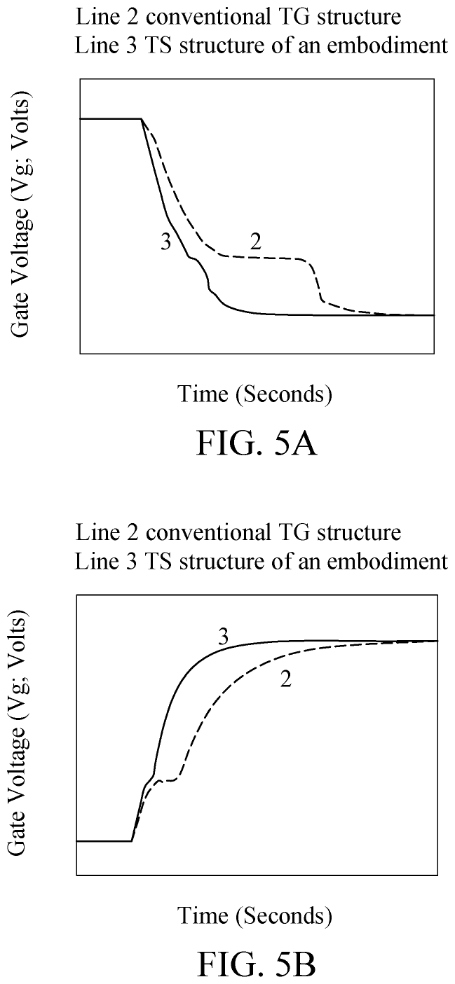

In addition, FIG. 5A is a simulation result that shows the gate voltage (Vg) changes with time when a conventional TG structure and a TS structure of an embodiment are in the off state. FIG. 5B is a simulation result that shows the gate voltage (Vg) changes with time when a conventional TG structure and a TS structure of an embodiment are in the on state. In addition, the results in FIG. 5A and FIG. 5B have indicated that, compared to the conventional TG structure (represented by line 2), the TS structure of the embodiment (represented by line 3) can be turned on or turned off more quickly, which means that the TS structure of the embodiment has a faster response time to turn on and turn off the device. In some simulation results, compared to the time for turning off the conventional TG structure, the time for turning off the TS structure of the embodiment can be reduced by about 61%. In addition, in some simulation results, compared to the time for turning on the conventional TG structure, the time for turning on the TS structure of the embodiment can be reduced by about 60%.

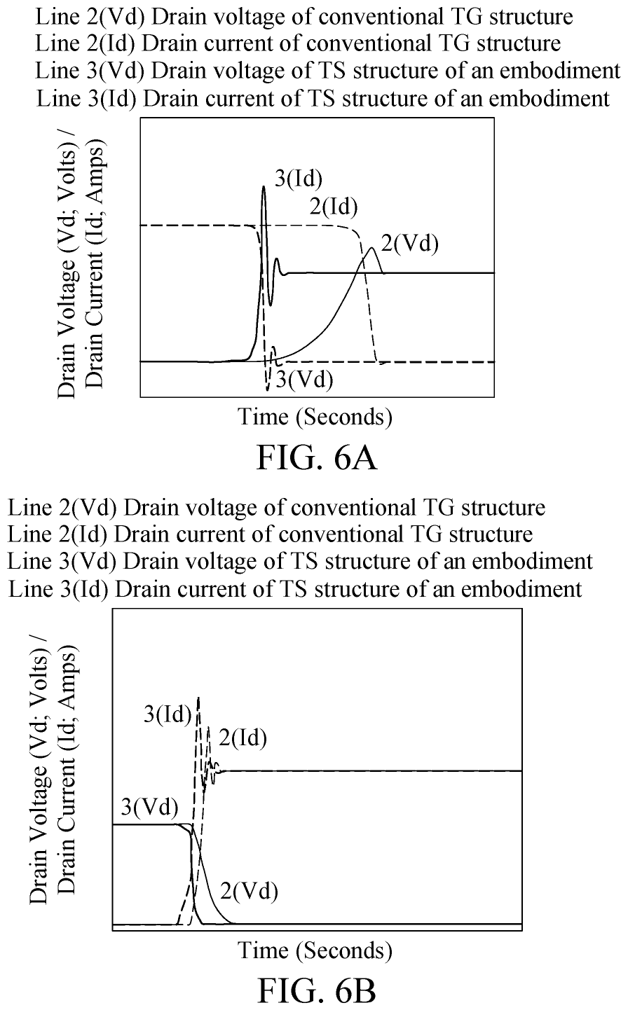

FIG. 6A is a simulation result that shows the drain voltage (Vd) or drain current (Id) changes with time when a conventional TG structure and a TS structure of an embodiment are in the off state. FIG. 6B is a simulation result that shows the drain voltage (Vd) or drain current (Id) changes with time when a conventional TG structure and a TS structure of an embodiment are in the on state. In FIG. 6A and FIG. 6B, line 2(Vd) represents the relationships of the drain voltage of the conventional TG structure with time. Line 2(Id) represents the relationships of the drain current of the conventional TG structure with time. In addition, line 3(Vd) represents the relationships of the drain voltage of the TS structure of the embodiment with time. Line 3(Id) represents the relationships of the drain current of the TS structure of the embodiment with time. In addition, an instantaneous power (i.e., the power measured at a given instant in time) can be obtained by multiplying the drain voltage and the drain current.

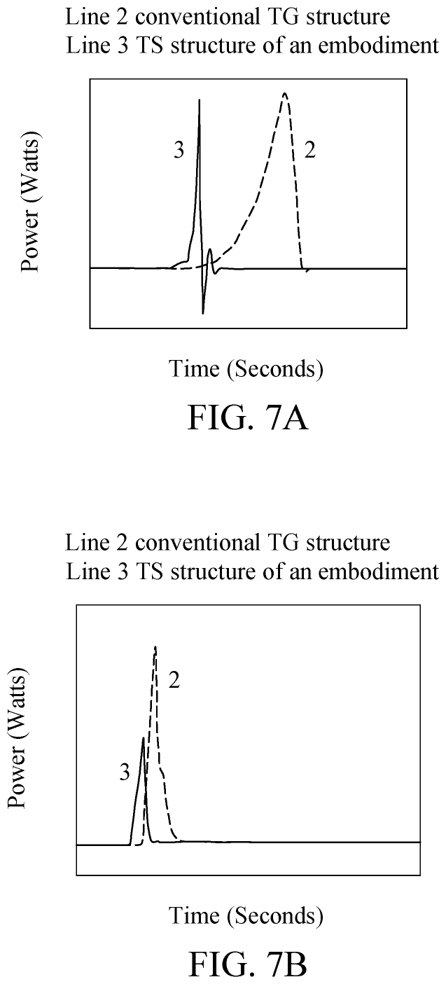

FIG. 7A is a simulation result that shows the power changes with time when a conventional TG structure and a TS structure of an embodiment are in the off state. FIG. 7B is a simulation result that shows the power changes with time when a conventional TG structure and a TS structure of an embodiment are in the on state. Energy is the integral of power with respect to time. Typically, the larger the area surrounded by power and time, the greater the switching energy loss during the dynamic switching. The results in FIG. 7A and FIG. 7B have indicated that the TS structure of the embodiment (represented by line 3) has less switching energy loss than the conventional TG structure (represented by line 2). Compared to the switching energy loss for turning on the conventional TG structure, the switching energy loss for turning on the TS structure of the embodiment can be reduced by about 68%, in accordance with the results of the dynamic characteristic simulations. In addition, compared to the switching energy loss for turning off the conventional TG structure, the switching energy loss for turning off the TS structure of the embodiment can be greatly reduced by about 85%, in accordance with the results of the dynamic characteristic simulations. In addition, if a complete operation cycling that includes turn-on and turn-off acts is taken for the measurement of the switching energy loss, the total switching energy loss (Etotal=Eon+Eoff) of the TS structure of the embodiment can be greatly reduced by about 80% compared to the total switching energy loss of the conventional TG structure, in accordance with the results of the dynamic characteristic simulations.

Therefore, according to some simulation results, even though the conventional TG structure and the TS structure of the embodiment have similar static characteristics, the TS structure of the embodiment has faster turn-off speed and faster turn-on speed than the conventional TG structure during the dynamic switching. In addition, compared to the switching energy loss of the conventional TG structure, the TS structure of the embodiment can greatly reduce the switching energy loss, in accordance with the results of the dynamic characteristic simulations.

According to the aforementioned descriptions, semiconductor devices and methods for forming the same, in accordance with some embodiments of the present disclosure, have many advantages. In some embodiments, the electrical performance of the semiconductor device that includes a trench structure adjacent to a body region (such as a p-type well region) can be greatly improved. In addition, one or more trench structures can be electrically connected to the gate structures to reduce the surface electric field (RESURF) and the on-resistance, in accordance with some embodiments of the present disclosure. Therefore, the semiconductor device that includes the trench structures electrically connected to the gate structures is suitable for a circuit system that is required for low frequency operation. In addition, the electrical connection in the semiconductor devices of the embodiments can be appropriately arranged depending on the practical requirements of the application. Thus, the semiconductor devices of the embodiments can be flexibly designed and suitable for the low-frequency operation or high-frequency operation through appropriate electrical connection. For example, one or more trench structures of the semiconductor device in accordance with some embodiments can be electrically connected to the source terminal to reduce the gate-to-drain capacitance (Cgd), which is suitable for forming the device that is operated at the high frequency. In addition, the semiconductor devices of the embodiments have greatly improved electronic characteristics. For example, the figure of merit (FOM) of the semiconductor device of some embodiments that includes the trench structure electrically connected to the source terminal (that is, the TS structure of the embodiment in the simulation tests) is very close to the figure of merit (FOM) of a conventional semiconductor device that includes the trench structure electrically connected to the gate electrode (that is, the conventional TG structure in the simulation tests). However, compared to the conventional semiconductor device, the semiconductor device of the embodiment has a faster response time when the semiconductor device is turned off and turned on. In addition, compared to the conventional semiconductor device, the switching energy loss of the semiconductor device of the embodiment can be greatly reduced, in accordance with the results of the dynamic characteristic simulations.

In addition, according to some embodiments, a semiconductor device that includes the trench structures with a higher density can be fabricated. For example, compared to the conventional semiconductor device (such as FIG. 3), the number of the trench structures in a cell unit of the semiconductor device of some embodiments (e.g., a cell unit having an area defined by the cell pitch CPH2 in FIG. 2) is twice the number of the trench structures in a cell unit of the conventional semiconductor device (e.g., a cell unit having an area defined by the cell pitch CPH0 in FIG. 3). If the trench structures are electrically connected to the gate structures (gate electrodes), the trench structures with higher density can enhance the field plate effect and achieve a better effect of reducing the surface electric field (RESURF). In addition, the trench structures that are formed in the semiconductor device in the embodiment does not occupy extra space of the epitaxial layer in the lateral direction (for example, in the second direction D2), and thus does not increase the lateral size of the semiconductor device. In addition, the method for forming the semiconductor device, in accordance with some embodiments of the present disclosure, can produce a semiconductor device with one or more trench structures through a simple process without adding additional photomasks and manufacturing steps. Also, the method for forming the semiconductor device of the embodiments is compatible with the existing processes. Accordingly, the methods of forming the semiconductor device, in accordance with some embodiments of the present disclosure, do not include complicated and expensive manufacturing processes, which save production time for fabricating the semiconductor device and do not increase the manufacturing cost.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate that has a first conductivity type;
an epitaxial layer on the substrate, wherein the epitaxial layer has the first conductivity type;
a trench structure extending downward from a top surface of the epitaxial layer into the epitaxial layer, wherein the trench structure comprises a conductive portion and an insulating layer that covers sidewalls and a bottom portion of the conductive portion;
a well region extending downward from the top surface of the epitaxial layer into the epitaxial layer, wherein the well region has a second conductivity type and a first sidewall of the well region is in contact with the trench structure, and wherein a drift region that has the first conductivity type is adjacent to and under the well region, and the drift region is in contact with a second sidewall and a bottom surface of the well region; and
a gate structure on the top surface of the epitaxial layer and over the well region.

2. The semiconductor device as claimed in claim 1, wherein a first side of the trench structure extends into the epitaxial layer along the first sidewall of the well region.

3. The semiconductor device as claimed in claim 2, wherein the first sidewall of the well region is in contact with an upper portion of the first side of the trench structure, and the drift region is in contact with a lower portion of the first side of the trench structure.

4. The semiconductor device as claimed in claim 1, wherein a bottom surface of the conductive portion of the trench structure is lower than the bottom surface of the well region.

5. The semiconductor device as claimed in claim 1, wherein the well region and the drift region are in direct contact with the insulating layer of the trench structure.

6. The semiconductor device as claimed in claim 1, further comprising:
a first heavily doped portion formed in the well region and extending from the top surface of the epitaxial layer into the epitaxial layer, wherein the first heavily doped portion has the first conductivity type, and the first heavily doped portion functions as a source region; and
a second heavily doped portion formed in the well region and adjacent to the trench structure, wherein the second heavily doped portion has the second conductivity type.

7. The semiconductor device as claimed in claim 6, further comprising:
a contact plug, disposed between the gate structure and the trench structure, wherein a bottom portion of the contact plug is in contact with the second heavily doped portion, wherein the drift region is not disposed between the contact plug and the trench structure.

8. The semiconductor device as claimed in claim 1, wherein the conductive portion of the trench structure is electrically connected to a source terminal of the semiconductor device.

9. The semiconductor device as claimed in claim 1, wherein the conductive portion of the trench structure is electrically connected to the gate structure.

10. The semiconductor device as claimed in claim 1, wherein the well region is a first well region adjacent to a first side of the trench structure, and the semiconductor 2 device further comprises:
a second well region extending downward from the top surface of the epitaxial layer into the epitaxial layer, wherein the second well region is adjacent to a second side of the trench structure, the second side is opposite the first side, and the second well region has the second conductivity type.

11. The semiconductor device as claimed in claim 10, wherein the second side of the trench structure extends into the epitaxial layer along a first sidewall of the second well region.

12. The semiconductor device as claimed in claim 11, wherein the first sidewall of the second well region is in contact with an upper portion of the second side of the trench structure, and the drift region is in contact with a lower portion of the second side of the trench structure.

13. The semiconductor device as claimed in claim 10, further comprising:
a third heavily doped portion formed in the second well region and adjacent to the second side of the trench structure, wherein the third heavily doped portion extends downward from the top surface of the epitaxial layer into the epitaxial layer, and the third heavily doped portion has the first conductivity type; and
a fourth heavily doped portion formed in the second well region and adjacent to the second side of the trench structure, wherein the fourth heavily doped portion has the second conductivity type.

14. The semiconductor device as claimed in claim 13, wherein the gate structure is a first gate structure, and the semiconductor device further comprises:
a second gate structure formed on the top surface of the epitaxial layer and corresponding to the second well region; and
a second contact plug disposed between the second gate structure and the trench structure, wherein a bottom portion of the second contact plug is in contact with the fourth heavily doped portion, and no portion of the drift region is disposed between the second contact plug and the trench structure.

15. A semiconductor structure comprising a plurality of the semiconductor devices as claimed in claim 1, wherein one or more of the trench structures of the semiconductor devices are electrically connected to one or more source terminals of the one or more semiconductor devices, and
wherein one or more remaining trench structures of the semiconductor devices are electrically connected to one or more gate structures of the semiconductor devices.

16. A method for forming a semiconductor device, comprising:
providing a substrate that has a first conductivity type;
forming an epitaxial layer on the substrate, wherein the epitaxial layer has the first conductivity type;
forming a trench structure that extends downward from a top surface of the epitaxial layer into the epitaxial layer; wherein the trench structure comprises a conductive portion and an insulating layer that covers sidewalls and a bottom portion of the conductive portion;
forming a well region that extends downward from the top surface of the epitaxial layer into the epitaxial layer, wherein the first sidewall of the well region is in contact with the trench structure, and the well region has the second conductivity type, wherein a drift region that has the first conductivity type is adjacent to one side of the well region and under the well region, wherein the drift region is in contact with a second sidewall and a bottom surface of the well region; and
forming a gate structure on the top surface of the epitaxial layer and over the well region.

17. The method for forming a semiconductor device as claimed in claim 16, wherein the first sidewall of the well region is in contact with an upper portion of the 2 first side of the trench structure, and the drift region is in contact with a lower portion of the first side of the trench structure.

18. The method for forming a semiconductor device as claimed in claim 16, wherein the bottom surface of the conductive portion of the trench structure is lower than the bottom surface of the well region, and the well region and the drift region are in direct contact with the insulating layer of the trench structure.

19. The method for forming a semiconductor device as claimed in claim 16, wherein before forming the gate structure, the method further comprises:
forming a first heavily doped portion by doping the well region from the top surface of the epitaxial layer into the epitaxial layer, wherein the first heavily doped portion has the first conductivity type, the first heavily doped portion is in contact with the insulating layer of the trench structure, and the gate structure corresponds to the underlying first heavily doped portion, and
after forming the gate structure, the method further comprises:
forming an interlayer dielectric layer (ILD) on the top surface of the epitaxial layer, wherein the interlayer dielectric layer covers the gate structure, the first heavily doped portion and the trench structure; and
removing a portion of the interlayer dielectric layer, a portion of the first heavily doped portion and a portion of the well region to form a contact hole, wherein a bottom portion of the contact hole exposes the well region.

20. The method for forming a semiconductor device as claimed in claim 19, further comprising:
forming a second heavily doped portion under the contact hole by doping the well region through the contact hole, wherein the second heavily doped portion is adjacent to the first heavily doped portion and the trench structure, and the second heavily doped portion has the second conductivity type; and
forming a contact plug in the contact hole, wherein the contact plug is formed between the gate structure and the trench structure, and a bottom portion of the contact plug is in contact with the second heavily doped portion,
wherein no portion of the drift region is disposed between the contact plug and the trench structure.

21. The method for forming a semiconductor device as claimed in claim 20, wherein the well region is a first well region and is adjacent to a first side of the trench structure, and a second well region is simultaneously formed from the top surface of the epitaxial layer into the epitaxial layer when the first well region is formed, and
wherein the second well region is adjacent to a second side of the trench structure, the second side is opposite the first side, the second well region has the second conductivity type, and the drift region is adjacent to one side of the second well region and under the second well region.

22. The method for forming a semiconductor device as claimed in claim 21, wherein the first sidewall of the second well region is in contact with an upper portion of the second side of the trench structure, and the drift region is in contact with a lower portion of the second side of the trench structure.

23. The method for forming a semiconductor device as claimed in claim 21, further comprising:
simultaneously forming a third heavily doped portion by doping the second well region when the first heavily doped portion is formed,
wherein the third heavily doped portion has the first conductivity type, and the third heavily doped portion is in contact with the insulating layer of the trench structure.

24. The method for forming a semiconductor device as claimed in claim 23, wherein the gate structure is a first gate structure, and the method further comprises:
simultaneously forming a second gate structure on the top surface of the epitaxial layer when the first gate structure is formed, wherein the second gate structure is formed over and corresponding to the second well region and the third heavily doped portion;
forming an interlayer dielectric layer (ILD) on the top surface of the epitaxial layer, wherein the interlayer dielectric layer covers the first gate structure, the first heavily doped portion, the trench structure, the third heavily doped portion and the second gate structure; and
removing portions of the interlayer dielectric layer, a portion of the first heavily doped portion, a portion of the first well region, a portion of the third heavily doped portion and a portion of the second well region to form a first contact hole and a second contact hole.

25. The method for forming a semiconductor device as claimed in claim 24, further comprising:
forming the second heavily doped portion by doping the first well region through the first contact hole, and forming the fourth heavily doped portion by doping the second well region through the second contact hole,
wherein the fourth heavily doped portion is formed under the third heavily doped portion and adjacent to the trench structure, and the fourth heavily doped portion has the second conductivity type.

26. The method for forming a semiconductor device as claimed in claim 25, further comprising:
forming a first contact plug in the first contact hole and a second contact plug in the second contact hole;
wherein the first contact plug is disposed between the first gate structure and the trench structure, and a bottom portion of the first contact plug is in contact with the second heavily doped portion;
the second contact plug is disposed between the second gate structure and the trench structure, and a bottom portion of the second contact plug is in contact with the fourth heavily doped portion; and
wherein no portion of the drift region is disposed between the first contact plug and the trench structure, and also no portion of the drift region is disposed between the second contact plug and the trench structure.
